(19) United States
(12) Patent Application Publication
(10) Pub. No.: US 2010/0278496 A1
(43) Pub. Date: Nov. 4, 2010

(54) OPTICAL WAVEGUIDE AND METHOD FOR PRODUCING THE SAME

(76) Inventors: Masatoshi Yamaguchi, Ibaraki (JP); Toshihiko Takasaki, Ibaraki (JP); Tokutarou Komatsu, Ibaraki (JP); Atsushi Takahashi, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/680,372

(22) PCT Filed: Sep. 24, 2008
(86) PCT No.: PCT/JP2008/067192

§ 371 Date: Jul. 16, 2010

(30) Foreign Application Priority Data
Sep. 26, 2007 (JP) 2007-249063
Apr. 2, 2008 (JP) 2008-096361

(51) Int. Cl. G02B 6/10; G03F 7/20

(52) U.S. Cl. 385/130; 430/321

(57) ABSTRACT

The present invention relates to an optical waveguide prepared by laminating a first cladding layer, a patterned core layer and a second cladding layer in this order on a base material, wherein the core layer has a height of 20 μm or more, and a curing rate in a range of 10 μm from a circumference of the core layer in the second cladding layer is 95% or more.

Capable of being provided are an optical waveguide which is prepared by using a resin for forming an optical waveguide and has an even core and an even clad and which is excellent in a transparency, a heat resistance and a productivity and a production process for the above optical waveguide which is excellent in a productivity,

### BACKGROUND OP THE INVENTION

The present invention relates to an optical waveguide which is excellent in a transparency, a heat resistance and a productivity and a production process for the same.

### RELATED ART

Development of optical interconnection techniques in which light signals are used not only for a telecommunication sector such as a trunk line and an access system but also for information processing in a router and a server is promoted as an information capacity is increased. To be specific, photoelectric mixed boards obtained by combining electric wiring boards with optical transmission paths are developed in order to use light for short distance signal transmission between boards or in boards in router and server devices.

Optical waveguides which have a high freedom in wiring and make it possible to increase the density as compared with optical fibers are preferably used, as optical transmission paths, and among them, optical waveguides prepared by using polymer materials which are excellent in a processability and an economical efficiency are promising.

On the other hand, an optical waveguide is required to have a high heat resistance as well as a high transparency in order to coexist with electric wiring boards, and fluorinated polyimide is proposed as a material for the above optical waveguide (refer to, for example, a non-patent document 1).

Fluorinated polyimide has a high heat resistance of 300° C. or higher and a high transparency of 0.3 dB/cm in a wavelength of 850 nm, but a condition of heating at 300° C. or higher for several ten minutes to several hours is required for forming a film thereof, and therefore it has been difficult to form the film on an electric wiring board. Further, since fluorinated polyimide does not have a photosensitivity, a method for preparing an optical waveguide by exposure and development can not be applied thereto, and it is inferior in a productivity and an expansion in an area.

Then, useful is a method in which a dry film containing a radiation-polymerizable component is laminated on a substrate and irradiated with a prescribed amount of a radiation to thereby cure a prescribed part thereof and in which a core part and the like are formed by developing, if necessary, an unexposed part, whereby an optical waveguide which is excellent in transmission characteristics is produced.

Use of the above method makes it easy to secure a flatness of a clad after a core is embedded and allows a distance between the cores in a thickness direction to be controlled at a good accuracy.

Further, it is suited for producing an optical waveguide having a large area (refer to, for example, patent documents 1 and 2).

An optical waveguide is constituted, as shown in the non-patent document 1, from a core for transmitting light signals and a clad which surrounds the core for reflecting wholly the light signals. A refractive index of the core is set usually higher than that of the clad in order to reflect wholly the light signals. Usually, a difference Δ in the refractive indices is controlled to 0.5 to 5%.

Accordingly, light coming in the core at a whole reflection angle or lower is not transmitted to a clad side due to whole reflection at a core/clad interface and is shut in the core. When a photosensitive clad is formed on a substrate in which a core is present, a non-exposed clad resin is formed on the core and then cured by irradiating a resin face thereof with an actinic ray.

A parallel light which is usually used for photolithograph is used for the above actinic ray. Among actinic rays coming from an upper face of the core, a wavelet coming in at a whole reflection angle or lower is not spread to a clad side, and therefore in a core/clad interface, the irradiation dose is reduced in a position farther than an actinic ray-irradiated side as compared with a region in which the core is not present.

Also, the core assumes an inverted taper form in a certain case, and in such case, an irradiation amount of an actinic ray is reduced in a clad of an inverted taper part. A situation in which photosensitization is scarcely brought about is generated in a certain case. Under such situation, a curing rate of the clad farther than an actinic ray-irradiated side of core/clad was low.

When an optical waveguide produced under the above situation was subjected to a reliability test such as a thermal cycle test, a high temperature and high humidity test and the like, the problem that a region having a low curing rate was deteriorated and reduced in optical characteristics was brought about. In this case, deterioration means, to be specific, that a void-like space is generated (refer to FIG. 3 and FIG. 8).

Further, when a parallel light was used for an actinic ray, there was a component which was removed from the light source in order to make the light parallel, and involved therein was the problem that the irradiation dose was reduced to require longer time for curing, so that the productivity was inferior.
Non-patent document 1: Electronics Mounting Academic Society Journal, Vol. 7, No. 3, pp. 213 to 218, 2004
Patent document 1: Japanese Patent Application Laid-Open No. 052120/2007
Patent document 2: Japanese Patent No. 3867409

### DISCLOSURE OF THE INVENTION

An object of the present invention is to provide an optical waveguide which is prepared by using a resin for forming an optical waveguide and has an even core and an even clad and which is excellent in a transparency and a heat resistance and a production process for the above optical waveguide which is excellent in a productivity.

Intensive investigations repeated by the present inventors have resulted in finding that the problems described above can be solved by a constitution or a process described below, and thus they have come to complete the present invention.

That is, the present invention provides:
(1) an optical waveguide prepared by laminating a first cladding layer, a patterned core layer and a second cladding layer in this order on a base material, wherein the core layer has a height of 20 μm or more, and a curing rate in a range of 10 μm from a circumference of the core layer in the second cladding layer is 95% or more,
(2) the optical waveguide according to the above item (1), wherein a layer having a haze of 5 or more is further provided on the second cladding layer,
(3) a production process for an optical waveguide comprising:

a first step in which a resin for forming a first cladding layer provided on a base material is cured to form the first cladding layer,

a second step in which a resin for forming a core layer is laminated on the above first cladding layer to form the core layer,

a third step in which the above core layer is exposed and developed to form a core pattern for an optical waveguide,

a fourth step in which the above core pattern is embedded by a resin for forming a second cladding layer,

a fifth step in which the above resin for forming a second cladding layer is cured by an actinic ray and

a sixth step in which the above second cladding layer is thermally cured,

wherein the actinic ray in the fifth step contains a scattered light having an incident angle of 5 degrees or more to a normal line direction of the base material,
(4) a production process for an optical waveguide comprising;

a first step in which a resin for forming a first cladding layer provided on a base material is cured to form the first cladding layer,

a second step in which a resin for forming a core layer is laminated on the above first cladding layer to form the core layer,

a third step in which the above core layer is exposed and developed to form a core pattern for an optical waveguide,

a fourth step in which the above core pattern is embedded by a resin for forming a second cladding layer,

a fifth step in which the above resin for forming a second cladding layer is cured by an actinic ray and

a sixth step in which the above second cladding layer is thermally cured,

wherein a layer having a haze of 5 or more is further provided on a resin layer formed by the resin for forming a second cladding layer in the fourth step,
(5) the production process for an optical waveguide according to the above item (4), wherein the actinic ray in the fifth step contains a scattered light having an incident angle of 5 degrees or more to a normal line direction of the base material,
(6) the production process for an optical waveguide according to any of the above items (3) to (5), wherein the core layer has a height of 20 μm or more, and a curing rate in a range of 10 μm from a circumference of the core layer in the second cladding layer is 95% or more and
(7) an optical waveguide produced by the process according to any of the above items (3) to (6).

According to the production process of the present invention, a clad of an inverted taper part can be irradiated with a satisfactory amount of an actinic ray even if the core assumes an inverted taper form, and therefore a curing rate of the clad farther than an actinic ray-irradiated side of core/clad can be enhanced. As a result thereof, a void-like space is not generated in a reliability test such as a thermal cycle test, a high temperature and high humidity test and the like, and an optical waveguide having a high reliability can be provided at a high productivity. Further, an optical waveguide produced by the process of the present invention is excellent in a transparency and a heat resistance.

### BRIEF EXPLANATION OF THE DRAWINGS

FIG. 1 is a cross-sectional drawing for explaining the optical waveguide of the present invention.

FIG. 2 is a drawing for explaining the production process for an optical waveguide according to the present invention.

FIG. 3 is a cross-sectional drawing for explaining a conventional optical waveguide.

FIG. 4 is a drawing for explaining a conventional production process for an optical waveguide.

FIG. 5 is a cross-sectional drawing for explaining the principle of the present invention.

FIG. 6 is a graph showing an irradiation amount (exposure) in the vicinity of a core to an incident angle of an actinic ray.

FIG. 7 is a graph showing relation of the haze with the void.

FIG. 8 is a graph showing a void which is the problem.

FIG. 9 is a graph showing the relation of the curing rate to the void.

FIG. 10 is a graph showing the relation of the exposure with a parallel light and a scattered light which is used for confirming the presence of voids'.

### EXPLANATION OF CODES

1 Base material
2 Lower cladding layer
3 Core layer
4 Support film (for forming a core layer)
5 Roll laminator
6 Vacuum pressure laminator
7 Photomask
8 Core pattern
9 Upper cladding layer
10 Support film (for forming a cladding layer)
12 Curing short area
13 Incident angle
14(a) Incident light
14(b) Incident light
14(c) Incident light
15 Void
20 Resin for forming a cladding layer
30 Resin for forming a core layer
40 Core periphery

### BEST MODE FOR CARRYING OUT THE INVENTION

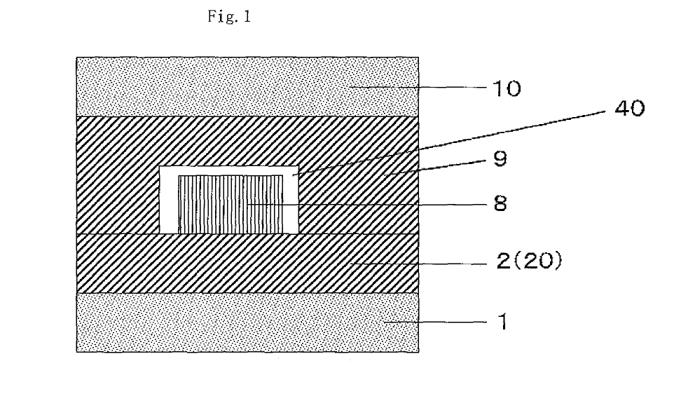

The optical waveguide of the present invention is an optical waveguide prepared by using a resin for forming one cladding layer having a high refractive index and resins for forming two cladding layers having a low refractive index. To be more detailed, the optical waveguide of the present invention is prepared, as shown in FIG. 1, by laminating a first cladding layer 1 (hereinafter referred to as “a lower cladding layer”), a patterned core layer 8 and a second cladding layer 9 (hereinafter referred to as “an upper cladding layer”) in this order on a base material 1, wherein the core layer 8 has a height of 20 μm or more, and a curing rate in a range 40 of 10 μm from a circumference of the core layer in the second cladding layer 9 is 95% or more.

In this connection, the curing rate is defined by a ratio of absorptions in specific wavelengths measured by an infrared absorption spectrometry. The specific wavelengths used for the measurement are different depending on the material used for the upper cladding layer in the optical waveguide, and in a case where, for example, a phenoxy resin is used as a base polymer described later in detail and where a compound having an epoxy group is used as a photopolymerizable compound, the above curing rate can be defined by a ratio of absorption in 790 cm⁻¹ originating in an epoxy group to absorption in 830 cm⁻¹ originating in an aromatic CH bond.

In the present invention, it is important that a curing rate in a range 40 (hereinafter referred to as “a core circumference”) of 10 μm from an outside of the core layer in the second cladding layer is 95% or more, and this makes it possible to inhibit a void-like space from being generated in the second cladding layer and provide an optical waveguide which is not reduced in optical characteristics by a reliability test such as a thermal cycle test, a high temperature and high humidity test and the like.

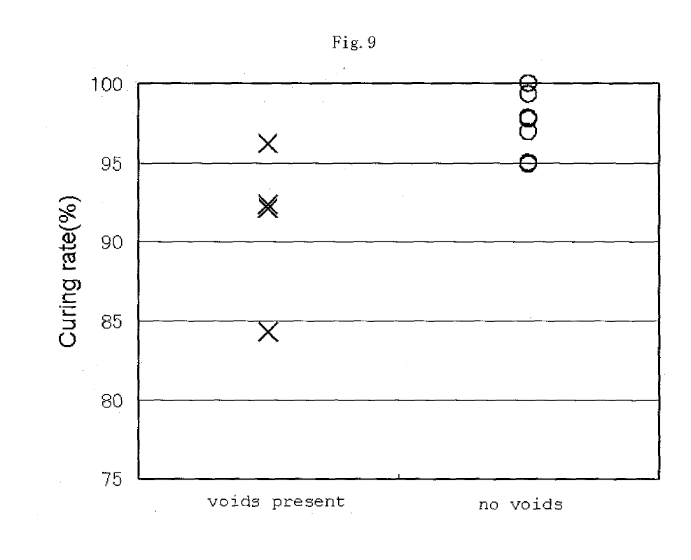

A result obtained by confirming experimentally the relation of the curing rate described above with the void is shown in FIG. 9. It has been clear that the curing rate of 95% or more makes it possible to inhibit the void at a high probability from being generated.

In the optical waveguide of the present invention, the core layer 8 has a height of 20 μm or more. If the core layer 8 has a height of 20 μm or more, provided is the advantage that a positioning tolerance can be extended in combination with a light receiving and emitting device or an optical fiber after forming the optical waveguide.

On the other hand, an upper limit value of a height of the core layer 8 shall not specifically be restricted as long as it falls in a range in which the functions of the optical waveguide are exerted, and it is preferably 100 μm or less from the viewpoint that a combination efficiency is enhanced in combination with a light receiving and emitting device or an optical fiber after forming the optical waveguide. From viewpoint described above, a height of the core layer 8 falls more preferably in a range of 30 to 70 μm.

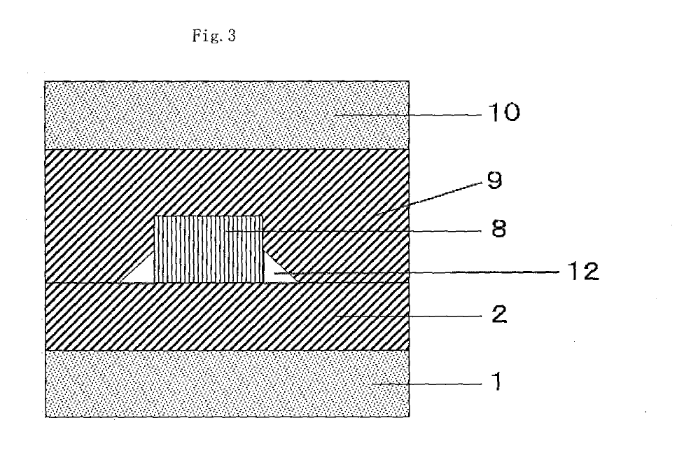

If the core layer 8 has a height of 20 μm or more, a curing rate of the cladding layer in a part far from an actinic ray irradiation side is lowered, and therefore a curing short area 12 is highly likely to be generated as shown in, for example, FIG. 3. In such case, the optical waveguide of the present invention in which a curing rate in the circumference of the core is 95% or more can be produced at a high productivity by using the production process of the present invention described later.

Also, in the optical waveguide of the present invention, a layer 10 having a haze of 5 or more is further provided preferably on the second cladding layer 9 (refer to FIG. 1). The above layer has a function of a support film for the second cladding layer 9 in the production process for an optical waveguide according to the present invention. Controlling a haze value of the above support film to 5 or more provides an effect of allowing an actinic ray to be scattered in curing the second cladding layer 9 by irradiating with an actinic ray to inhibit the curing short area 12 from being generated.

In this connection, the haze is prescribed in JIS K 7105 and defined by the following equation:

Haze (%)=[whole light transmittance (%)−parallel light transmittance (%))/[whole light transmittance (%)]

The haze is measured by means of a haze meter (NDH2000, manufactured by Nippon Denshoku Industries Co., Ltd.) using a D65 light source. The relation of the haze with generation of the void is shown in FIG. 7. It can be found that the void ceases from being generated when the haze is 5 or more.

A resin material constituting the optical waveguide of the present invention may be either film-like or liquid, and considering no flowing in the production process and a flatness of the cladding layer and the core layer, a film-like material prepared by laminating the resins for forming the respective layers on the support film is preferably used. The production process of the present invention shall be explained below in detail with reference to the drawings taking as an example thereof, a case of using the film-like material.

The production process of the present invention comprises:

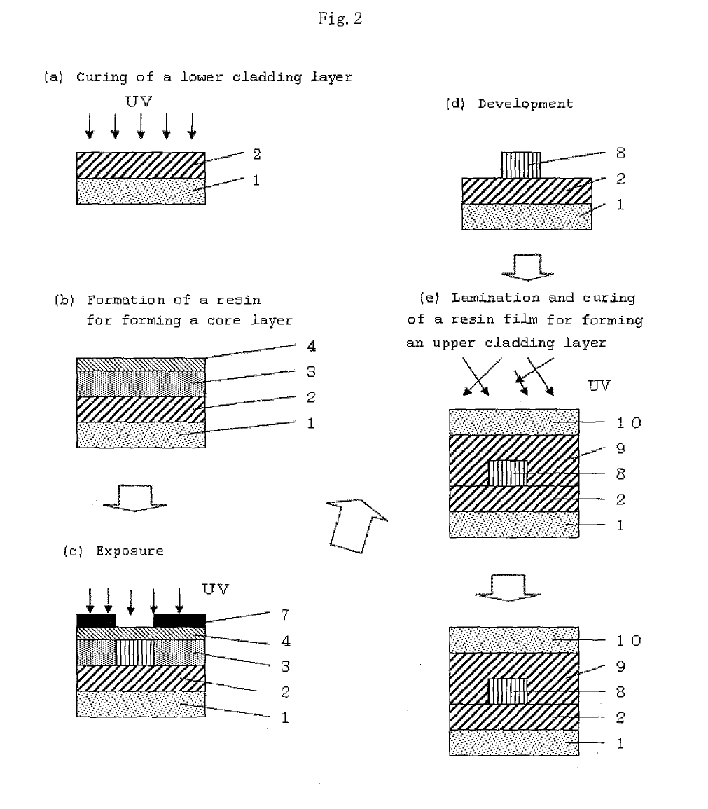

a first step (FIG. 2(a)) in which a resin for forming a first cladding layer provided on a base material is cured to form the first cladding layer 2 (a lower cladding layer),

a second step (FIG. 2(b)) in which a resin for forming a core layer is laminated on the above first cladding layer to form the core layer,

a third step (FIG. 2(c) and FIG. 2(d)) in which the above core layer is exposed and developed to form a core pattern for an optical waveguide,

a fourth step (FIG. 2(e)) in which the above core pattern is embedded by a resin for forming a second cladding layer,

a fifth step (FIG. 2(e)) in which the above resin for forming a second cladding layer is cured by an actinic ray and

a sixth step in which the above second cladding layer is thermally cured. It is characterized by that the actinic ray in the fifth step contains a scattered light having an incident angle of 5 degrees or more to a normal line direction of the base material.

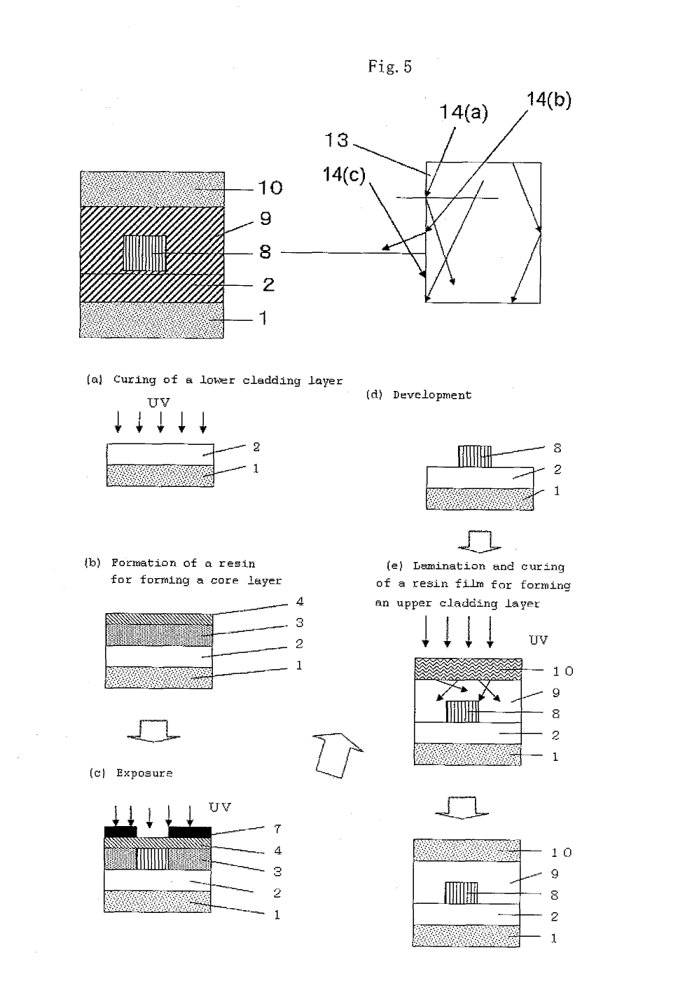

In the production process of the present invention, it is important that the actinic ray in the fifth step contains, as described above, a scattered light having an incident angle of 5 degrees or more to a normal line direction of the base material. Use of the above scattered light makes it possible to cure better the resin for forming a cladding layer which is located in a core/clad interface farther than an actinic ray-irradiated side. That is, use of the above scattered light makes it possible to lower a whole reflection angle at which light is wholly reflected in the core and reduce an influence of guiding a wave in the core, and therefore the clad in the vicinity of the core can efficiently be cured (refer to FIG. 5).

That is, light having a small incident angle 13 (light having an incident angle of less than 5 degrees) as is the case with an incident light 14(a) in FIG. 5 is wholly reflected on a side wall of the core and can not come in the clad.

On the other hand, light having a larger incident angle (light having an incident angle of 5 degrees or more) than the whole reflection angle as is the case with an incident light 14(b) in FIG. 5 is varied in a transmission angle but can come in the clad, and it can contribute to curing of the clad. Further, when a scattered light is used, light like an incident light 14(c) in FIG. 5 is present and enhances the curing rate in the vicinity of the core.

From the viewpoints described above, the scattered light described above is preferably light containing a component having an incident angle of 10 degrees or more, more preferably light containing a component having an incident angle of 15 degrees or more.

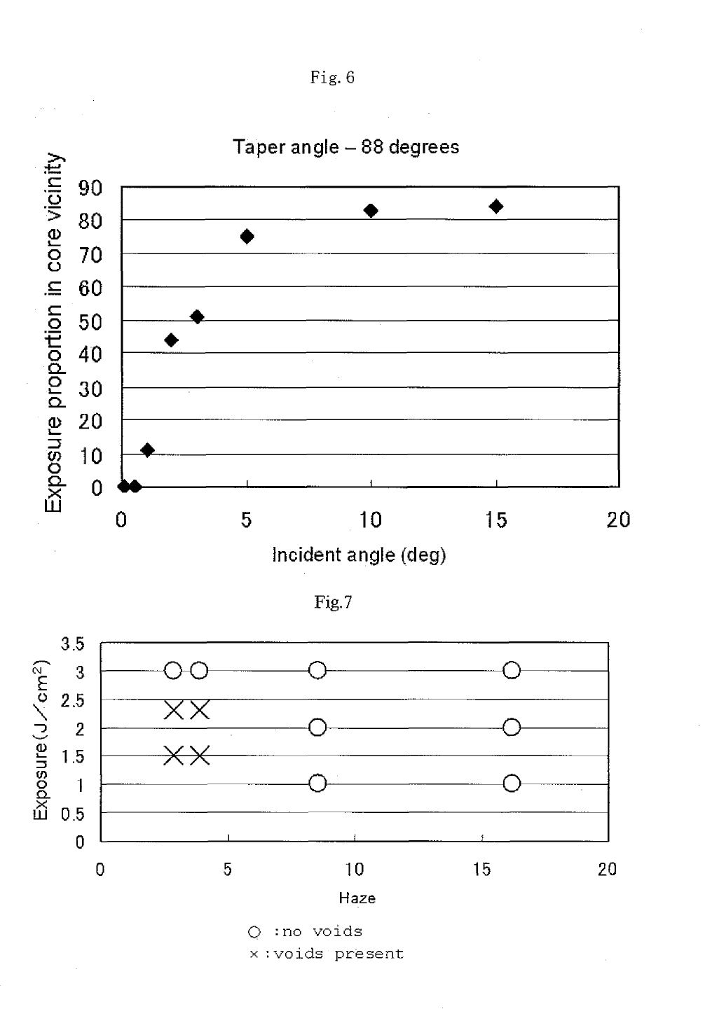

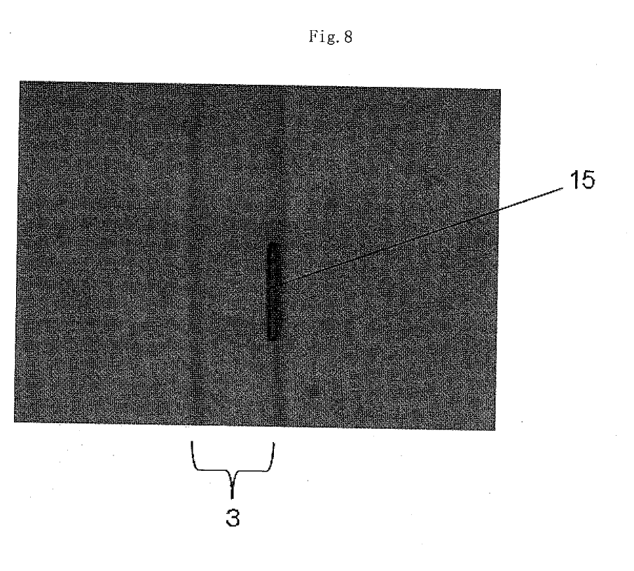

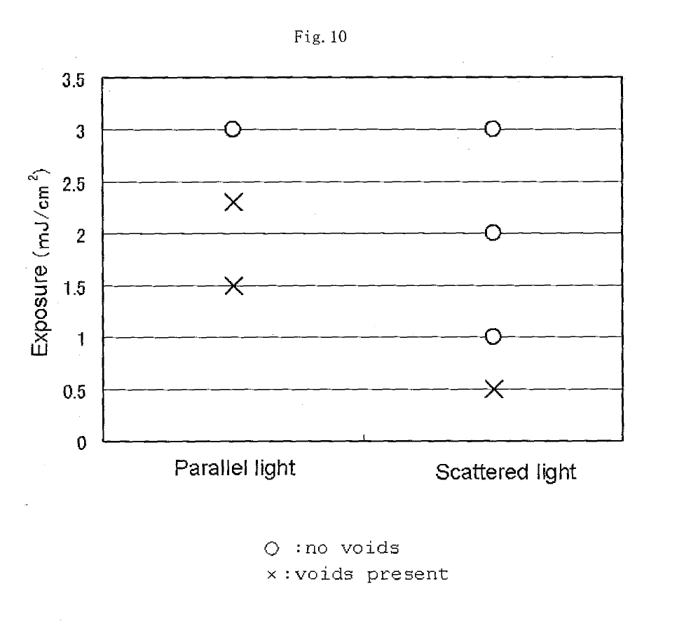

Further, use of the above scattered light makes it unnecessary to remove surplus direction components and can elevate the irradiation intensity, and therefore time needed for curing can be shortened to make it possible to enhance the productivity. Simulation carried out for the above incident angle according to a ray tracing method (Light Tools ver. 5.2.0) has resulted in finding that when the incident angle is 5 degrees or more, the exposure in the vicinity of the core is almost saturated (refer to FIG. 6). In respect to generation of voids when exposed to light containing an incident light having an incident angle of 5 degrees or more and a parallel light, the voids can be inhibited from being generated by a lower exposure, as shown in FIG. 10, in a case where exposure is carried out by a scattered light, and as a result thereof, the productivity is enhanced.

Further, in the production process of the present invention, a layer 10 having a haze of 5 or more is further provided preferably on the resin layer formed by the resin for forming a second cladding layer in the fourth step. The above layer has a function of a support film for the second cladding layer 9 in the production process for the optical waveguide. In the production process of the present invention, an actinic ray is scattered by setting a haze value of the above support film to 5 or more even when a parallel actinic ray is radiated to cure the second cladding layer 9, and a curing short area 12 is inhibited from being generated. A scattered light is more preferably used as an actinic ray, and the curing short area 12 can more effectively be inhibited from being generated (refer to FIG. 5(e)).

Next, the production process of the present invention shall be explained in detail by every step.

In the first step in the production process of the present invention, the resin for forming a first cladding layer provided on the base material is cured to form the first cladding layer.

The kind of the base material shall not specifically be restricted, and, for example, FR-4 substrates, polyimide substrates, semiconductor substrates, silicon substrates, glass substrates and the like can be used.

Also, the optical waveguide can be provided with a flexibility and a toughness by using a film as the base material 1.

A material constituting the film described above shall not specifically be restricted, and from the viewpoint of having a flexibility and a toughness, it includes suitably polyesters such as polyethylene terephthalate, polybutylene terephthalate, polyethylene naphthalate and the like and in addition thereto, polyethylene, polypropylene, polyamide, polycarbonate, polyphenylene ether, polyether sulfide, polyallylate, liquid crystal polymers, polysulfone, polyethersulfone, polyether ether ketone, polyetherimide, polyamide-imide, polyimide and the like.

When the film is used as the base material 1 shown in FIG. 1, a resin film for forming a cladding layer which is prepared in advance can be used as it is. That is, the resin for forming a cladding layer in the resin film for forming a first cladding layer which is constituted from the resin 20 for forming a cladding layer and the support film 1 as the base material 1 is cured to form the cladding layer 2 (refer to FIG. 2(a)). A surface of the above cladding layer 2 is preferably flat. The resin film for forming a cladding layer may be transferred on the base material 1 by using a lamination method and the like.

When a protective film is provided on an opposite side to the support film 1 of the resin film for forming a cladding layer, the above protective film is peeled off, and then the resin film for forming a cladding layer is cured by light or heating to form the cladding layer 2. In this case, a film of the resin for forming a cladding layer is preferably formed on the support film 1 subjected to adhesion treatment. This makes it possible to enhance an adhesive force between the lower cladding layer 2 and the base material 1 and inhibit inferior peeling between the lower cladding layer 2 and the base material 1.

In this connection, the adhesion treatment is treatment for enhancing an adhesive force between the support film 1 and the cladding layer 20 formed thereon by mat processing carried out by readily-adhesive resin coating, corona treatment, sand blast and the like.

On the other hand, the protective film is preferably not subjected to adhesion treatment in order to make it easy to peel from the resin film for forming a cladding layer, and it may be subjected, if necessary, to release treatment. In a case where a base material 1 different from the support film is used as the base material 1, when a protective layer for the resin film for forming a cladding layer is present on the base material 1, the resin film for forming a cladding layer is transferred on the base material 1 by a lamination method using a roll laminator after the protective layer is peeled off, and the support film is peeled off. Then, the resin for forming a cladding layer is cured by light or heating to form the cladding layer 2.

A thickness of the support film may suitably be changed according to the targeted flexibility, and it is preferably 5 to 250 μm. If it is 5 μm or more, the advantage that the toughness is liable to be obtained is provided, and if it is 250 μm or less, the satisfactory flexibility is obtained.

Also, a film of the resin 20 for forming a cladding layer may be formed on the support film which is not subjected to adhesion treatment and transferred on the base material 1 by a lamination method.

Further, a multilayer optical waveguide having a plurality of upper cladding, lower cladding and core layers in a multistage manner on one surface or both surfaces of the base material 1 described above may be prepared.

Further, electric wirings may be provided on the base material 1 described above, and in this case, a base material on which electric wirings are provided in advance can be used as the base material 1. Or, electric wirings can be formed on the base material 1 after producing a multilayer optical waveguide. This makes it possible to provide both of signal transmitting lines of metal wirings on the base material 1 and signal transmitting lines of the optical waveguide and use both in a proper way and makes it possible to readily transmit signals at a high speed in a long distance.

The resin 20 for forming a cladding layer used in the present invention shall not specifically be restricted as long as it is a resin composition which has a lower refractive index than that of the core layer and which is cured by light, and a photosensitive resin composition can be used.

More suitably, the resin 20 for forming a cladding layer is constituted preferably from a resin composition containing (A) a base polymer, (B) a photopolymerizable compound and (C) a photopolymerization initiator.

The base polymer (A) is used above in order to form the cladding layer and secure a strength of the above cladding layer, and it shall not specifically be restricted as long as the above object can be achieved. It includes phenoxy resins, epoxy resins, (meth)acryl resins, polycarbonate resins, polyallylate resins, polyetheramide, polyetherimide, polyethersulfone and the like or derivatives thereof. The above base polymers may be used alone or in a mixture of two or more kinds thereof. Among the base polymers shown above as the examples, the polymers having an aromatic skeleton in a principal chain are preferred from the viewpoint that they have a high heat resistance, and the phenoxy resins are particularly preferred.

Also, the epoxy resins, particularly the epoxy resins which are solid at room temperature are preferred from the viewpoint that they can three-dimensionally be cross-linked and improved in a heat resistance.

Further, a compatibility thereof with the photopolymerizable compound (B) described later in detail is important in order to secure a transparency of the resin for forming a cladding layer, and from the above viewpoint, the phenoxy resins and the (meth)acryl resins each described above are preferred. In this connection, the (meth)acryl resins mean acryl resins and methacryl resins.

Among the phenoxy resins, the resins containing bisphenol A or bisphenol A type epoxy compounds or derivatives thereof and bisphenol F or bisphenol F type epoxy compounds or derivatives thereof as constitutional units for a copolymer component are preferred since they are excellent in a heat resistance, an adhesive property and a solubility. The derivatives of bisphenol A or the bisphenol A type epoxy compounds include suitably tetrabromobisphenol A, tetrabromobisphenol A type epoxy compounds and the like.

Also, the derivatives of bisphenol F or the bisphenol F type epoxy compounds include suitably tetrabromobisphenol F, tetrabromobisphenol F type epoxy compounds and the like. The specific examples of bisphenol A/bisphenol F copolymer type phenoxy resins include “Phenotote YP-70” (trade name) manufactured by Tohto Kasei Co., Ltd.

The epoxy resins which are solid at room temperature include, for example, bisphenol A type epoxy resins such as “Epotote YD-7020, Epotote YD-7019 and Epotote YD-7017” (all trade names) manufactured by Tohto Kasei Co., Ltd. and “Epikote 1010, Epikote 1009 and Epikote 1008” (all trade names) manufactured by Japan Epoxy Resins Co., Ltd.

Next, the photopolymerizable compound (B) shall not specifically be restricted as long as it is polymerized by irradiating with light such as a UV ray and the like, and it includes compounds having two or more epoxy groups in a molecule and compounds having an ethylenically unsaturated group in a molecule.

Also, the photopolymerization initiator of the component (C) shall not specifically be restricted, and the initiators for the epoxy compounds include, for example, aryldiazonium salts, diaryliodonium salts, triarylsulfonium salts, triallylselenonium salts, dialkylphenazylsulfonium salts, dialkyl-4-hydroxyphenylsulfonium salts, sulfonic acid esters and the like.

Also, the initiators for the compounds having an ethylenically unsaturated group in a molecule include aromatic ketones such as benzophenone and the like, quinones such as 2-ethylanthraquinone and the like, benzoin ether compounds such as benzoin methyl ether and the like, benzoin compounds such as benzoin and the like, benzyl derivatives such as benzyl dimethyl ketal and the like, 2,4,5-triarylimidazole dimers such as 2-(o-chlorophenyl)-4,5-diphenylimidazole dimers and the like, phosphine oxides such as bis(2,4,6-trimethylbenzoyl)phenylphosphine oxide and the like, acridine derivatives such as 9-phenylacridine and the like, N-phenylglycine, N-phenylglycine derivatives, coumarin base compounds and the like.

Also, thioxanthone base compounds may be combined with tertiary amine compounds as is the case with combination of diethyl thioxanthone with dimethylaminobenzoic acid. Among the compounds described above, the aromatic ketones and the phosphine oxides are preferred from the viewpoint of enhancing a transparency of the core layer and the cladding layer.

The above photopolymerization initiators (C) can be used alone or in combination of two or more kinds thereof.

Also, in addition to the above compounds, so-called additives such as an antioxidant, a yellowing inhibitor, a UV absorber, a visible light absorber, a colorant, a plasticizer, a stabilizing agent, a filler and the like may be added to the resin 20 for forming a cladding layer according to the present invention in proportions exerting no adverse influences to the effects of the present invention.

The resin film for forming a cladding layer can readily be produced by dissolving the resin composition containing the components (A) to (C) in a solvent, coating the solution on the support film described above and removing the solvent. In this case, a protective film may be stuck, if necessary, on the resin film for forming a cladding layer in terms of protection of the resin film for forming a cladding layer and a rolling property thereof in producing it in a roll form.

The same ones as those listed as the examples of the support film can be used as the protective film, and it may be subjected, if necessary, to release treatment and antistatic treatment. The solvent used above shall not specifically be restricted as long as it can dissolve the above resin composition, and capable of being used are, for example, solvents such as acetone, methyl ethyl ketone, methyl cellosolve, ethyl cellosolve, toluene, N,N-dimethylacetamide, propylene glycol monomethyl ether, propylene glycol monomethyl ether acetate, cyclohexanone, N-methyl-2-pyrrolidone and the like, or mixed solvents thereof. A solid matter concentration in the resin solution is preferably 30 to 80% by mass.

A thickness of the cladding layers 2 and 9 falls preferably in a range of 5 to 500 μm in terms of a thickness after drying. If it is 5 μm or more, a clad thickness necessary for shutting light in can be secured, and if it is 500 μm or less, it is easy to control evenly the film thickness. From the viewpoints described above, a thickness of the cladding layers 2 and 9 falls more preferably in a range of 10 to 100 μm.

The thicknesses of the cladding layers 2 and 9 may be the same or different in the lower cladding layer 2 which is first formed and the upper cladding layer 9 for embedding the core pattern, and a thickness of the upper cladding layer 9 is preferably larger than that of the core layer 3 in order to embed the core pattern.

Next, in the second step, the resin for forming a core layer is laminated on the cladding layer 2 described above to form the core layer. Also in this case, the resin film for forming a core layer is preferably used, as described above, in laminating the resin for forming a core layer. To be more specific, the resin film for forming a core layer is pressed on the cladding layer 2 by means of a roll laminator to form the core layer 3. In this case, the roll may be heated in pressing, and the temperature falls preferably in a range of room temperature to 100° C. If it exceeds 100° C., the core layer flows in roll laminating, and the film thickness required is not obtained. The pressure is preferably 0.2 to 0.9 MPa. The laminating speed is preferably 0.1 to 3 m/minute, but the above conditions shall not specifically be restricted.

Next, a composite film prepared by laminating the core layer 3 on the cladding layer 2 is heated and pressed thereon by means of a flat plate type laminator. In the above second step, the resin film for forming a core layer is heated and pressed on the cladding layer 2 described above to thereby laminate the core layer 3 having a higher refractive index than that of the cladding layer 2. In this case, the core layer 3 is laminated preferably under reduced pressure from the viewpoint of an adhesive property and a followability. The vacuum degree which is a measure of reduced pressure is preferably 10000 Pa or less, more preferably 1000 Pa or less.

The vacuum degree is preferably lower from the viewpoint of an adhesive property and a followability, and from the viewpoint of a productivity (time required for vacuuming), a lower limit thereof is about 10 Pa. In this case, the heating temperature is preferably 40 to 130° C., and the pressing pressure is preferably 0.1 to 1.0 MPa (1 to 10 kgf/cm²), but the above conditions shall not specifically be restricted. The resin film for forming a core layer is constituted preferably from a core resin and a support film 4 (FIG. 2(b)) since handling thereof is easy, and it may be constituted from the core layer resin alone.

When a protective film is provided on a side opposite to the base material for the resin film for forming a core layer, the above protective film is peeled off, and then the resin film for forming a core layer is laminated. In this case, the protective film and the support film 4 are preferably not subjected to adhesion treatment in order to facilitate peeling from the resin film for forming a core layer, and they may be subjected, if necessary, to release treatment.

The resin film for forming a core layer used in the present invention is designed so that the core layer 3 has a higher refractive index than those of the cladding layers 2 and 9. A resin composition which can form a core pattern 8 by an actinic ray can be used therefor, and a photosensitive resin composition is suited. To be specific, the same resin composition as that used in the resins 2 and 9 for forming a cladding layer described above is preferably used. That is, it is a resin composition containing the components (A), (B) and (C) described above and containing, if necessary, the optional components described above

The resin film for forming a core layer can readily be produced by dissolving the resin composition containing the components (A) to (C) in a solvent, coating the solution on the base material and removing the solvent. In this case, a protective film may be stuck, if necessary, on the resin film for forming a core layer in terms of protection of the resin film for forming a core layer and a rolling property thereof in producing it in a roll form. The same ones as those listed as the examples of the support film can be used as the protective film, and it may be subjected, if necessary, to release treatment and antistatic treatment.

The solvent used above shall not specifically be restricted as long as it can dissolve the above resin composition, and capable of being used are, for example, solvents such as acetone, methyl ethyl ketone, methyl cellosolve, ethyl cellosolve, toluene, N,N-dimethylformamide, N,N-dimethylacetamide, propylene glycol monomethyl ether, propylene glycol monomethyl ether acetate, cyclohexanone, N-methyl-2-pyrrolidone and the like, or mixed solvents thereof. A solid matter concentration in the resin solution is preferably 30 to 80% by mass.

A thickness of the resin film for forming a core layer is controlled so that the above thickness of the core layer is obtained. That is, it is controlled so that a thickness of the core layer after drying is usually 20 to 100 μm, and it is controlled preferably in a range of 30 to 70 μm.

The support film used in the production process of the resin film for forming a core layer is a support film for supporting a film for forming an optical waveguide. A material thereof shall not specifically be restricted and includes suitably polyesters such as polyethylene terephthalate and the like, polypropylene, polyethylene and the like from the viewpoints that it is easy to peel off the resin film for forming a core layer later and that they have a heat resistance and a solvent resistance.

A thickness of the above support film is preferably 5 to 50 μm. If it is 5 μm or more, the advantage that a strength of the above support film is liable to be obtained is provided, and if it is 50 μm or less, provided is the advantage that a gap thereof with a mask in forming patterns is reduced to make it possible to form finer patterns. From the viewpoints described above, a thickness of the above support film falls in a range of more preferably 10 to 40 μm, particularly preferably 15 to 30 μm.

Next, the core layer 3 is exposed and developed to form a core pattern 8 for an optical waveguide in the third step. To be specific, the core layer is irradiated imagewise with an actinic ray through a photomask pattern 7 (refer to FIG. 2(c)). A light source of the actinic ray includes, for example, publicly known light sources which effectively radiate a UV ray, such as a carbon arc lamp, a mercury vapor arc lamp, a ultra high pressure mercury lamp, a high pressure mercury lamp, a xenon lamp and the like. Further, in addition thereto, lamps which effectively radiate a visible light, such as a flood bulb for photograph, a sun lamp and the like can be used as well.

The actinic ray used above may be either a scattered light having an incident angle of 5 degrees or more to a normal line direction of the base material or a parallel light.

Next, when the support film 4 of the resin film for forming a core layer remains, the support film 4 is peeled off, and the unexposed part is removed by wet development and the like and developed to form a core pattern 8 (refer to FIG. 2(d)). In a case of wet development, an organic solvent base developer which is suited to the composition of the film described above is used to carry out development by a publicly known method such as spraying, swing dipping, brushing, scraping and the like.

The organic solvent base developer includes, for example, N-methylpyrrolidone, N,N-dimethylformamide, N,N-dimethylacetamide, cyclohexanone, methyl ethyl ketone, methyl isobutyl ketone, γ-butyrolactone, methyl cellosolve, ethyl cellosolve, propylene glycol monomethyl ether, propylene glycol monomethyl ether acetate and the like. Two or more kinds of developing methods may be used, if necessary, in combination.

The developing method includes, for example, a dipping method, a puddle method, a spraying method such as a high pressure spraying method and the like, brushing, scraping and the like, and the high pressure spraying method is most suited for enhancing the resolution.

The core pattern 8 which is further cured, if necessary, by heating at 60 to 250° C. or exposing to 0.1 to 1000 mJ/cm² as treatment after development may be used.

Then, the resin film for forming a cladding layer is laminated in order to embed the core pattern 8 in the fourth step, and the resin for forming a cladding layer in the above resin film for forming a cladding layer is cured to cure the cladding layer 9 in the fifth step. When the resin film for forming a cladding layer comprises the resin for forming a cladding layer and a support film 10, the resin for forming a cladding layer is laminated on a core pattern 8 side. In this case, a thickness of the cladding layer 9 is preferably larger, as described above, than a thickness of the core layer 3.

The curing is carried out by an actinic ray in the same manner as described above. A light source of the actinic ray includes, for example, publicly known light sources which effectively radiate a UV ray, such as a carbon arc lamp, a mercury vapor arc lamp, a ultra high pressure mercury lamp, a high pressure mercury lamp, a xenon lamp and the like. Further, in addition thereto, lamps which effectively radiate a visible light, such as a flood bulb for photograph, a sun lamp and the like can be used as well. In this regard, the actinic ray is preferably, as described above, a scattered light having no directionality.

When a protective film is provided on a side opposite to the support film 10 of the resin film for forming a cladding layer, the above protective film is peeled off, and then the resin film for forming a cladding layer is cured by light or heating to form the cladding layer 9. In this case, a film of the resin for forming a cladding layer is preferably formed on the support film 10 subjected to adhesion treatment.

On the other hand, the above protective film is preferably not subjected to adhesion treatment in order to make it easy to peel from the resin film for forming a cladding layer, and it may be subjected, if necessary, to release treatment.

### Examples

The present invention shall more specifically be explained below with reference to examples, but the present invention shall by no means be restricted by these examples;

### Example 1

### (Preparation of Resin Films for Forming a Core Layer and a Cladding Layer)

Resin compositions for forming a core layer and a cladding layer were prepared according to compositions shown in Table 1, and ethyl cellosolve was added thereto as a solvent in an amount of 40 parts by mass based on the whole amount to prepare resin vanishes for a core layer and a cladding layer.

TABLE 1

| | Base | Photopolymerizable | Polymerization |
|---|---|---|---|
| | polymer (A) | compound (B) | initiator (C) |
| Core | Phenotote | A-BPEF*² | 2,2-Bis(2-chloropnenyl)- |
| | YP-70*¹ | (39 mass parts) | 4,4′,5,5′-tetraphenyl- |
| | (20 mass parts) | | 1,2′-biimidazole*⁵ |
| | | | (1 mass part) |
| | | EA-1020*³ | 4,4′-Bis(diethylamine)- |
| | | (39 mass parts) | benzophenone*⁶ |
| | | | (0.5 mass part) |
| | | | 2-Mercaptobenzimidazole*⁷ |
| | | | (0.5 mass part) |
| Clad | Phenotote | KRM-2110*⁴ | SP-170*⁸ (2 mass parts) |
| | YP-70*¹ | (63 mass parts) | |
| | (35 mass parts) | | |

*¹Phenotote YP-70, bisphenol A/bisphenol F copolymer type phenoxy resin, manufactured by Tohto Kasei Co., Ltd.
*²A-BPEF, 9,9-bis[4-(2-acryloyloxyethoxy)phenyl]fluorene, manufactured by Shin-Nakamura Chemical Co., Ltd.
*³EA-1020, bisphenol A type epoxy acrylate, manufactured by Shin-Nakamura Chemical Co., Ltd.
*⁴KRM-2110, alicyclic diepoxy carboxylate, manufactured by Shin-Nakamura Chemical Co., Ltd.
*⁵2,2-bis(2-chloropnenyl)-4,4′,5,5′-tetraphenyl-1,2′-biimidazole, manufactured by Tokyo Chemical Industry Co., Ltd.
*⁶4,4′-bis(diethylamino)benzophenone, manufactured by Tokyo Chemical Industry Co., Ltd.
*⁷2-mercaptobenzimidazole, manufactured by Tokyo Chemical Industry Co., Ltd.
*⁸SP-170, triphenylsulfonium hexafluoroantimonate salt, manufactured by Adeka Corporation.

This was coated on a PET film (trade name: COSMOSHINE A1517, manufactured by Toyobo Co., Ltd., thickness: 16 μm, haze: 0.9) by means of an applicator (YBA-4, manufactured by Yoshimitsu Seiki Co. Ltd.) (resin film for forming a cladding Mayer: adhesion-treated surface in an inside was used, resin film for forming a core layer: non-treated surface in an outside was used), and the solvent was dried on the conditions of 10 minutes at 80° C., then 10 minutes at 100° C. to obtain a resin film for forming a core layer and a cladding layer.

In this regard, a thickness of the film could optionally be controlled in a range of 5 to 100 μm by controlling a gap of the applicator, and in the present example, it was controlled so that the film thicknesses after dried were 40 μm in the core layer, 20 μm in the lower cladding layer and 70 μm in the upper cladding layer.

The resin film for forming a lower cladding layer was optically cured by irradiating with 1000 mJ/cm² of a UV ray (wavelength: 365 nm) by means of a UV ray exposing equipment (MAP-1200, manufactured by Dainippon Screen Mfg. Co., Ltd.) (refer to FIG. 2(a)).

Next, lamination was carried out on the above cladding layer at a pressure of 0.4 MPa, a temperature of 50° C. and a laminating speed of 0.2 m/minute by means of a roll laminator (HLM-1500, manufactured by Hitachi Chemical Co., Ltd.).

Thereafter, vacuuming was carried out at 500 Pa or less by means of a vacuum press laminator (MVLP-500, manufactured by Meiki Co., Ltd.) as a flat plate type laminator, and then the resin film for forming a core layer was laminated on the conditions of a pressure of 0.4 MPa, a temperature of 70° C. and a pressing time of 30 seconds (refer to FIG. 2(b)).

Subsequently, the resin was irradiated with 1000 mJ/cm² of a UV ray (wavelength: 365 nm) via a photomask (negative type) having a width of 40 μm by means of the UV ray exposing equipment described above (refer to FIG. 2(c)), and then the core pattern was developed by a 8:2 mass ratio mixed solvent of ethyl cellosolve and N,N-dimethylacetamide (refer to FIG. 2(d)). Methanol and water were used for washing the developer away.

Thereafter, vacuuming was carried out at 500 Pa or less by means of the vacuum press laminator (MVLP-500, manufactured by Meiki Co., Ltd.), and then the resin film for forming an upper cladding layer was laminated on the laminating conditions of a pressure of 0.4 MPa, a temperature of 70° C. and a pressing time of 30 seconds. It was irradiated with 3.6 J/cm² of a UV ray having an irradiation intensity of 10 mW/cm² in 365 nm as an actinic ray by means of a scattered UV ray irradiation equipment (Eyedolphin 3000, manufactured by Eye Graphics Co., Ltd.) and then it was subjected to heat treatment at 110° C. for one hour to prepare an optical waveguide (refer to FIG. 2(e)). Further, a sample having a waveguide length of 10 cm was cut out from the prepared optical waveguide by dicing.

A clad in the vicinity of the core and a clad far from the core were taken from the above sample cut out for analysis of the optical waveguide by dicing and measured by means of an infrared spectrophotometer FT-IR1760X (manufactured by PerkinElmer Inc.) to find that a curing rate of the clad in the vicinity of the core was 96%.

The refractive indices of the core layer and the cladding layer were measured by means of a prism coupler (Model 12010) manufactured by Metricon Corporation to find that a refractive index of the core layer was 1.584 in a wavelength of 850 nm and that a refractive index of the cladding layer was 1.537.

LED of 855 nm (Q81201, manufactured by Advantest Corporation) for a light source and a photosensitive sensor (Q82214, manufactured by Advantest Corporation) were used to measure the propagation loss by an incident fiber: GI-50/125 multimode fiber (NA=0.20), an output fiber: SI-114/125 (NA=0.22) and an incident light: an effective core diameter 26 μm to find that it was 1.5 dB.

Further, the degradation loss after 100 cycles of thermal cycle at −50° C./125° C. (keeping time: 15 minutes) was 0.1 dB or less, and the degradation loss at −50° C./85% RH for 500 hours was 0.1 dB or less.

### Example 2

An optical wave guide was prepared in the same manner as in Example 1, except that in Example 1, E5000 (haze: 5.7) manufactured by Toyobo Co., Ltd. was used as the support film 10 and that 1 J/cm² of a UV ray (wavelength: 365 nm) was radiated as an actinic ray by a parallel UV ray exposing equipment (MAP-1200, manufactured by Dainippon Screen Mfg. Co., Ltd.) having an irradiation intensity of 10 mW/cm² in 365 nm.

A sample was cut out for analysis of the optical waveguide by dicing in the same manner as in Example 1, and a clad in the vicinity of the core and a clad far from the core were taken from the sample and measured by means of the infrared spectrophotometer FT-IR1760X (manufactured by PerkinElmer Inc.) to find that a curing rate of the clad in the vicinity of the core was 96%.

The refractive indices of the core layer and the cladding layer were measured by means of the prism coupler (Model 12010) manufactured by Metricon Corporation to find that a refractive index of the core layer was 1.584 in a wavelength of 850 nm and that a refractive index of the cladding layer was 1.537.

LED of 855 nm (Q81201, manufactured by Advantest Corporation) for a light source and the photosensitive sensor (Q82214, manufactured by Advantest Corporation) were used to measure the propagation loss by the incident fiber: GI-50/125 multimode fiber (NA=0.20), the output fiber: SI-114/125 (NA=0.22) and the incident light: an effective core diameter 26 μm to find that it was 1.5 dB.

Further, the degradation loss after 100 cycles of thermal cycle at −50° C./125° C. (keeping time: 15 minutes) was 0.1 dB or less, and the degradation loss at −50° C./85% RH for 500 hours was 0.1 dB or less.

### Example 3

An optical wave guide was prepared in the same manner as in Example 1, except that in Example 1, E5000 (haze: 5.7) manufactured by Toyobo Co., Ltd. was set at an actinic ray incoming side in exposing to carry out exposure.

A sample was cut out for analysis of the optical waveguide by dicing in the same manner as in Example 1, and a clad in the vicinity of the core and a clad far from the core were taken from the sample and measured by means of the infrared spectrophotometer FT-IR1760X (manufactured by PerkinElmer Inc.) to find that a curing rate of the clad in the vicinity of the core was 96%.

The refractive indices of the core layer and the cladding layer were measured by means of the prism coupler (Model 12010) manufactured by Metricon Corporation to find that a refractive index of the core layer was 1.584 in a wavelength of 850 nm and that a refractive index of the cladding layer was 1.537.

LED of 855 nm (Q81201, manufactured by Advantest Corporation) for a light source and the photosensitive sensor (Q82214, manufactured by Advantest Corporation) were used to measure the propagation loss by the incident fiber: GI-50/125 multimode fiber (NA=0.20), the output fiber: SI-114/125 (NA=0.22) and the incident light: an effective core diameter 26 μm to find that it was 1.5 dB.

Further, the degradation loss after 100 cycles of thermal cycle at −50° C./125° C. (keeping time: 15 minutes) was 0.1 dB or less, and the degradation loss at −50° C./85% RH for 500 hours was 0.1 dB or less.

### Comparative Example 1

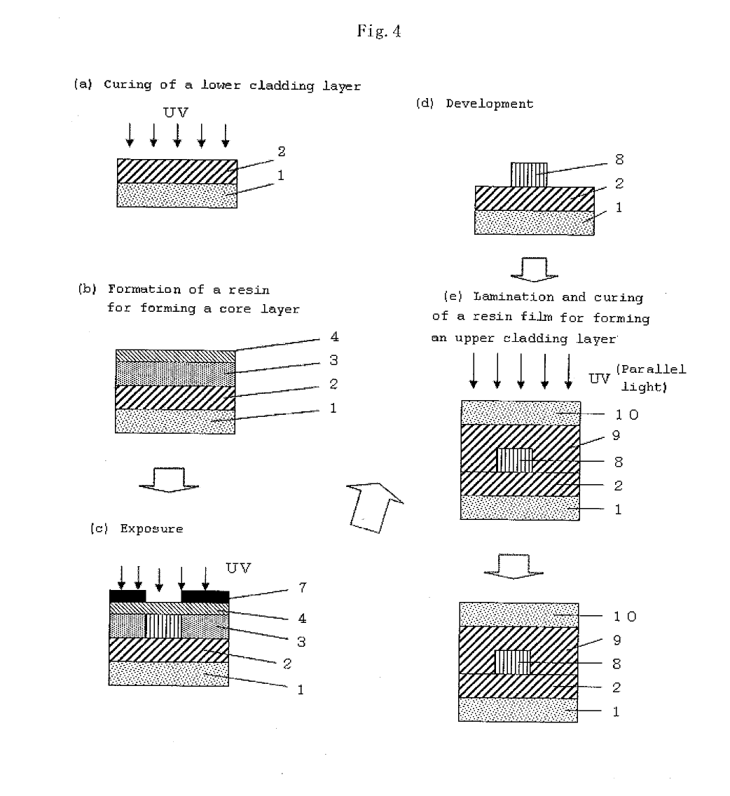

An optical wave guide was prepared in the same manner as in Example 1, except that in Example 1, the clad resin was exposed by a parallel light exposing equipment (MAP1200L, manufactured by Dainippon Screen Mfg. Co., Ltd.) (refer to FIG. 4). In this case, the irradiation intensity in 365 nm was controlled to 8 mW/cm², and the irradiation dose was controlled to 3.6 J/cm². Then, heat treatment was carried out at 110° C. for one hour.

A sample was cut out from the optical waveguide thus prepared by dicing in the same manner as in Example 1, and a clad in the vicinity of the core and a clad far from the core were taken from the sample and measured by means of the infrared spectrophotometer FT-IR1760X (manufactured by PerkinElmer Inc.) to find that a curing rate of the clad in the vicinity of the core was 90%.

LED of 855 nm (Q81201, manufactured by Advantest Corporation) for a light source and the photosensitive sensor (Q82214, manufactured by Advantest Corporation) were used to measure the propagation loss by the incident fiber: GI-50/125 multimode fiber (NA=0.20), the output fiber: SI-114/125 (NA=0.22) and the incident light: an effective core diameter 26 μm to find that it was 1.5 dB, and the initial value was the same as in the examples.

Further, the degradation loss after 100 cycles of thermal cycle at −50° C./125° C. (keeping time: 15 minutes) was 0.3 dB, and the degradation loss at −50° C./85% RH for 500 hours was 0.3 dB. An increase in the loss was large as compared with those of the examples.

### INDUSTRIAL APPLICABILITY

According to the production process of the present invention, a clad of an inverted taper part can be irradiated with a satisfactory amount of an actinic ray even if the core assumes an inverted taper form. Accordingly, a curing rate of the clad far from an actinic ray-irradiated side of core/clad can be enhanced even by irradiation for short time. As described above, a high curing rate of the clad prevents a void-like space from being generated in a reliability test such as a thermal cycle test, a high temperature and high humidity test and the like and makes it possible to provide an optical waveguide which has a high reliability and which is excellent in a transparency and a heat resistance at a high productivity.

1. An optical waveguide prepared by laminating a first cladding layer, a patterned core layer and a second cladding layer in this order on a base material, wherein the core layer has a height of 20 μm or more, and a curing rate in a range of 10 μm from a circumference of the core layer in the second cladding layer is 95% or more.

2. The optical waveguide according to claim 1, wherein a layer having a haze of 5 or more is further provided on the second cladding layer.

3. A production process for an optical waveguide comprising:
a first step in which a resin for forming a first cladding layer provided on a base material is cured to form the first cladding layer,
a second step in which a resin for forming a core layer is laminated on the above first cladding layer to form the core layer,
a third step in which the above core layer is exposed and developed to form a core pattern for an optical waveguide,
a fourth step in which the above core pattern is embedded by a resin for forming a second cladding layer,
a fifth step in which the above resin for forming a second cladding layer is cured by an actinic ray and
a sixth step in which the above second cladding layer is thermally cured,
wherein the actinic ray in the fifth step contains a scattered light having an incident angle of 5 degrees or more to a normal line direction of the base material.

4. A production process for an optical waveguide comprising:
a first step in which a resin for forming a first cladding layer provided on a base material is cured to form the first cladding layer,
a second step in which a resin for forming a core layer is laminated on the above first cladding layer to form the core layer,
a third step in which the above core layer is exposed and developed to form a core pattern for an optical waveguide,
a fourth step in which the above core pattern is embedded by a resin for forming a second cladding layer,
a fifth step in which the above resin for forming a second cladding layer is cured by an actinic ray and
a sixth step in which the above second cladding layer is thermally cured,
wherein a layer having a haze of 5 or more is further provided on a resin layer formed by the resin for forming a second cladding layer in the fourth step.

5. The production process for an optical waveguide according to claim 4, wherein the actinic ray in the fifth step contains a scattered light having an incident angle of 5 degrees or more to a normal line direction of the base material.

6. The production process for an optical waveguide according to claim 3, wherein the core layer has a height of 20 μm or more, and a curing rate in a range of 10 μm from a circumference of the core layer in the second cladding layer is 95% or more.

7. An optical waveguide produced by the process according to claim 3.

8. The production process for an optical waveguide according to claim 4, wherein the core layer has a height of 20 μm or more, and a curing rate in a range of 10 μm from a circumference of the core layer in the second cladding layer is 95% or more.

9. An optical waveguide produced by the process according to claim 4.
